(19) United States
(12) Patent Application Publication
(10) Pub. No.: US 2013/0106469 A1
(43) Pub. Date: May 2, 2013

(54) CONTROL CONTACT DRIVING SYSTEM

(71) Applicant: ABB TECHNOLOGY AG, Zurich (CH)

(72) Inventors: Nedyalko SLAVOV, Zurich (CH); Raffael Schnell, Seon (CH)

(73) Assignee: ABB TECHNOLOGY AG, Zurich (CH)

(21) Appl. No.: 13/660,638

(22) Filed: Oct. 25, 2012

(30) Foreign Application Priority Data
Oct. 26, 2011 (EP) 11186714.9

(51) Int. Cl. H03K 17/06

(52) U.S. Cl. CPC H03K 17/063
USPC 327/109

(57) ABSTRACT

A control contact driving system for a plurality of power semiconductor devices includes a driver unit providing reference currents for pulling-up and/or pushing-down control contacts of the semiconductor devices, and a distributor unit amplifying and/or distributing the reference currents to the control contacts. The current distributor unit includes a pull-up current mirror having a plurality of PMOS based transistors, and a push-down current mirror having a plurality of NMOS based transistors. First main contacts of all pull-up transistors are connected in parallel to a first voltage source, and first main contacts of all push-down transistors are connected in parallel to a second voltage source. Second main contacts of a respective one of the pull-up transistors and push-down transistors are connected together for providing current to a respective control contact. The control contacts of the pull-up transistors and the push-down transistors are all connected in parallel to the current driver unit.

### RELATED APPLICATION

This application claims priority under 35 U.S.C. §119 to European Patent Application No. 11186714.9 filed in Europe on Oct. 26, 2011, the entire content of which is hereby incorporated by reference in its entirety.

### FIELD

The present disclosure relates to a control contact driving system for a plurality of power semiconductor devices. The present disclosure also relates to a power semiconductor module including the control contact driving system and a plurality of power semiconductor devices. In addition, the present disclosure relates to a power semiconductor array including a plurality of modified power semiconductor modules, and to a method for operating the control contact driving system, the power semiconductor module and/or the modified power semiconductor module.

### BACKGROUND INFORMATION

Power semiconductor devices, such as insulated gate bipolar transistors (IGBT), reverse conductive insulated gate bipolar transistors (reverse conducting IGBT) and/or bi-mode insulated gate transistors (BIGT), are mostly used as a fast switching device for very high electrical currents and voltages. The popularity of IGBTs is rising due to their excellent electrical properties and relatively easy driving. They are widely used in applications such as electrical motor control equipment, for example, for hybrid and electrical cars, locomotives, ship propulsions, industrial equipment, machineries etc., DC electrical transmission, such as DC-AC converters, wind and solar power converters and synchronizers, power network cosinus φ compensators, emergency power supplies, etc.

Often, a plurality of IBGT dies are connected in parallel encapsulated in a module to increase their switching capabilities, as shown in the known configuration of FIG. 1. However, in such parallel connection of the gates, a defect in a gate and especially a short circuit connection between a gate and an emitter makes all of the IGBT devices in the module uncontrollable.

### SUMMARY

An exemplary embodiment of the present disclosure provides a control contact driving system for a plurality of power semiconductor devices. The exemplary control contact driving system includes a current driver unit configured for providing reference currents for at least one of pulling-up and pushing-down control contacts of the power semiconductor devices, and a current distributor unit configured for at least one of amplifying and distributing the reference currents to the control contacts of the power semiconductor devices. The current distributor unit includes a pull-up current mirror having a plurality of PMOS based transistors, and a push-down current mirror having a plurality of NMOS based transistors. First main contacts of all pull-up transistors are connected in parallel to a first voltage source, and first main contacts of all push-down transistors are connected in parallel to a second voltage source having a lower voltage than the first voltage source. A second main contact of a corresponding one of the pull-up transistors and a second main contact of a corresponding one of the push-down transistors are respectively connected together and configured for providing current to a respective control contact of a corresponding one of the power semiconductor devices, respectively. The control contacts of the pull-up transistors are all connected in parallel to the current driver unit for receiving a pull-up current, and the control contacts of the push-down transistors are all connected in parallel to the current driver unit for receiving a push-down current.

An exemplary embodiment of the present disclosure provides a power semiconductor module which includes the above-described control contact driving system according to the present disclosure, and a plurality of power semiconductor devices. The control contact of a corresponding one of the power semiconductor devices is connected to the second main contact of a respective pull-up transistor and to the second main contact of a respective push-down transistor.

An exemplary embodiment of the present disclosure provides a power semiconductor array which includes a plurality of modified power semiconductor modules having a plurality of power semiconductor devices. The exemplary array also includes a current driver unit configured for providing reference currents for at least one of pulling-up and pushing-down control contacts of the power semiconductor devices, and a modified current distributor unit configured for at least one of amplifying and distributing the reference currents to the power semiconductor modules. The modified power semiconductor modules each include a plurality of power semiconductor devices and a current distributor unit configured for at least one of amplifying and distributing the reference currents to the power semiconductor devices. The current distributor unit includes a pull-up current mirror having a plurality of PMOS based transistors, and a push-down current mirror having a plurality of NMOS based transistors. First main contacts of all pull-up transistors are connected in parallel to a first voltage source, and first main contacts of all push-down transistors are connected in parallel to a second voltage source having a lower voltage than the first voltage source. A second main contact of a corresponding one of the pull-up transistor and a second main contact of a corresponding one of the push-down transistor are connected together with a respective control contact of a corresponding one of the power semiconductor devices, respectively. The control contacts of the pull-up transistors are all connected in parallel to the modified current distributor unit for receiving a pull-up current, and the control contacts of the push-down transistors are all connected in parallel to the modified current distributor unit for receiving a push-down current. The modified current distributor unit includes a plurality of PMOS based transistors and a plurality of NMOS based transistors. The control contacts of the PMOS based transistors are connected together to the current driver unit for receiving the push-down current, and the control contacts of the NMOS based transistors are connected together to the current driver unit for receiving the pull-up current. The second main contact of a corresponding one of the PMOS based transistors is coupled to a respective modified power semiconductor module for providing the pull-up current, and the second main contact of the respective modified power semiconductor module for providing the push-down current.

An exemplary embodiment of the present disclosure provides a method for operating any of the above-described control contact driving system, power semiconductor module and/or power semiconductor array, where the method includes providing, by the current driver unit, a positive rectangular current as a pull-up reference current followed by a negative rectangular current as a push-down reference current.

### BRIEF DESCRIPTION OF THE DRAWINGS

Additional refinements, advantages and features of the present disclosure are described in more detail below with reference to exemplary embodiments illustrated in the drawings, in which:

FIG. 1 shows a known connection of a plurality of IGBTs in parallel;

FIG. 2 shows a known connection of the parallel IGBTs as shown in FIG. 1 in a serial connection with IGBT drivers;

FIG. 3 shows the so-called Miller effect;

FIG. 4 shows a simplified circuit and wave forms for the gate-emitter voltage and currents according to known configurations;

FIG. 5 shows an individual gate driving according to a known configuration;

FIG. 6 shows the mismatch created by technological tolerances between drivers according to known configurations;

FIG. 7 shows three current levels during the transition phase according to known configurations;

FIG. 8 shows a current drive mode according to an exemplary embodiment of the present disclosure;

FIG. 9 shows a control contact driving system according to an exemplary embodiment of the present disclosure;

FIG. 10 shows a power semiconductor module according to an exemplary embodiment of the present disclosure;

FIG. 11 shows a possible placement of four IGBTs and two freewheeling diodes mounted on a substrate including the control contact driving system according to an exemplary embodiment of the present disclosure;

FIG. 12 shows a power semiconductor array according to an exemplary embodiment of the present disclosure;

FIG. 13 shows an example of a pull-up current and push-down current for operating the control contact driving system according to an exemplary embodiment of the present disclosure;

FIG. 14 shows a current sensor according to an exemplary embodiment of the disclosure;

FIG. 15 shows an example of a current distributor unit according to an exemplary embodiment of the present disclosure;

FIGS. 16 to 18 and 20 to 22 show simulation results achieved with control contact driving systems according to exemplary embodiments of the present disclosure as shown in FIGS. 15 and 19, respectively; and

FIG. 19 shows an exemplary embodiment of an implementation of a power semiconductor module including the control contact driving system according to the present disclosure.

### DETAILED DESCRIPTION

Exemplary embodiments of the present disclosure provide a control contact driving system for driving the control contacts of a plurality of power semiconductor devices, for example, IGBTs, such that a short circuit between a control contact and a main contact of a power semiconductor device, for example, between a gate and an emitter of an IGBT, does not affect overall stability and/or controllability of the whole system.

Exemplary embodiments of the present disclosure also provide a power semiconductor module including the control contact driving system and a plurality of power semiconductor devices, a power semiconductor array including a plurality of modified power semiconductor modules, and a method for operating the control contact driving system, the power semiconductor module and/or the modified power semiconductor module

In accordance with an exemplary embodiment, a control contact driving system is provided for a plurality of power semiconductor devices, where the system includes a current driver unit configured (e.g., adapted) for providing reference currents for pulling-up and/or pushing-down the control contacts of the power semiconductor devices, and a current distributor unit configured for amplifying and/or distributing the reference currents to the control contacts of the power semiconductor devices. The current distributor unit includes a pull-up current mirror which includes a plurality of PMOS based transistors, and a push-down current mirror which includes a plurality of NMOS based transistors. The first main contacts of all pull-up transistors are connected in parallel to a first voltage source, and the first main contacts of all push-down transistors are connected in parallel to a second voltage source having a lower voltage than the first voltage source. The second main contact of a respective pull-up transistor and the second main contact of a respective push-down transistor are connected together and configured for providing current to a respective control contact of a power semiconductor device. The control contacts of the pull-up transistors are all connected in parallel to the current driver unit for receiving a pull-up current, and the control contacts of the push-down transistors are all connected in parallel to the current driver unit for receiving a push-down current.

Accordingly, the present disclosure provides current mirrors for further amplifying and/or distributing currents for switching the individual control contacts of a plurality of power semiconductor devices, for example amplifying and/or distributing positive and negative current pulses to the gates of a multi-die IGBT module. In this such way, the control contact driving system provides for driving more than a single control contact respectively more than a single power semiconductor device. As the control contacts of the individual power semiconductor devices are driven individually, respectively, a failure of a control contact, such as a short circuit connection between a gate and emitter of an IGBT power semiconductor device, does not make all of the power semiconductor devices uncontrollable. The control contact driving system and/or the current driver unit can be implemented as a circuit, such as a hybrid or even better integrated circuit, and can be capsulated within the power semiconductor module, therefore in close contact to the controlled devices, such as transistors, for example.

The control contact driving system provides for equal switching processes for all power semiconductor devices connected, for example connected in parallel, by providing equal driving currents to the control contacts of the power semiconductor devices, thereby avoiding the mismatch from using individual control contact drivers, as known according to conventional techniques. In accordance with an exemplary embodiment, all electrical devices used within the control contact driving system are provided with “well” matched electrical properties and placed in an equal environment in terms of temperature, supply voltage etc., such that the respective driving currents for the control contacts of the power semiconductor devices are also “well” matched.

In accordance with an exemplary embodiment, the power semiconductor devices are provided as insulated gate bipolar transistor (IGBT), reverse conductive insulated gate bipolar transistor (reverse conducting IGBT), bi-mode insulated gate transistor (BIGT) and/or any other power MOSes. The control contact can be provided as the gate, the first main contact can be provided as the emitter, and/or the second main contact can be provided as the collector of the power semiconductor device, for example, an IGBT. In accordance with an exemplary embodiment, the first voltage source provides a voltage greater than zero and/or the second voltage source provides a voltage smaller than zero or a voltage that is zero with respect to a main contact of the power semiconductor device, for example, grounded to earth. In accordance with an exemplary embodiment, the current for respectively pulling-up the pull-up current transistors includes a current that is greater than zero and/or the current for respectively pushing-down the push-down transistors includes a current that is smaller than zero. In regards to the pull-up transistors and/or the push-down transistors, the control contact can include the gate, the first main contact can include the source and/or the second main contact can include the drain of the respective transistor. In accordance with an exemplary embodiment, aforementioned transistors are provided as field effect transistors.

In accordance with an exemplary embodiment, the pull-up current mirror includes a PMOS based pull-up reference transistor, and the push-down current mirror includes a NMOS based push-down reference transistor. The first main contact of the pull-up reference transistor is connected to all first main contacts of the pull-up transistors, and the first main contact of the push-down reference transistor is connected to all first main contacts of the push-down transistors. The control contact of the pull-up reference transistor is connected to the control contacts of the pull-up transistors, and the control contact of the push-down reference transistor is connected to the control contacts of the push-down transistors. The second main contact of the push-up reference transistor is connected to the current driver unit for receiving the pull-up current, and the second main contact of the push-down reference transistor is connected to the current driver unit for receiving the push-down current. Thus, according to this embodiment, the current, for example, current pulses coming from the current driver unit, is applied to the reference transistor, which can be in a “diode” connection for defining the bias voltage for the pull-up transistors respectively push-down transistors.

In accordance with an exemplary embodiment, the control contact driving system includes a current sensor for detecting a malfunction of a control contact of a power semiconductor device, whereby the current sensor is connected to the first main contacts of the pull-up transistors and/or to the first main contacts of the push-down transistors. This embodiment is advantageous for detecting shorted gates, as the current sensor is configured for measuring the value of the current flowing towards the current distributor unit and for activating an alarm, for example, in case the value is greater than a predefined threshold.

In accordance with an exemplary embodiment, the pull-up current mirror includes a plurality of PMOS based voltage limiting devices, and the push-down current mirror includes a plurality of NMOS based voltage limiting devices. At least one voltage limiting device is connected in series with its main contacts between the pull-up transistor or the push-down transistor and the push-down respectively the pull-up transistor. In accordance with an exemplary embodiment, the voltage limiting device is provided as a cascading transistor. Providing such voltage limiting devices as cascading transistors, respectively, allows for limiting the voltage across the transistor directly connected to the power semiconductor devices and for using low voltage CMOS technology for relatively high operating voltages.

Exemplary embodiments of the present disclosure also provide a power semiconductor module including the control contact driving system as described above and a plurality of power semiconductor devices, whereby the control contact of a respective power semiconductor device is connected to the second main contact of a respective pull-up transistor and to the second main contact of a respective push-down transistor.

In accordance with an exemplary embodiment, the power semiconductor devices are arranged in groups such that the first main contacts of the power semiconductor devices of the respective group are all connected in parallel and such that the second main contacts of the power semiconductor devices of the respective group are all connected in parallel.

In accordance with an exemplary embodiment, at least the second main contacts of a first group are connected to the first main contacts of a second group. Arranging the power semiconductor devices in such groups allows for switching higher voltages respectively currents.

According to an exemplary embodiment, the plurality of power semiconductor devices and the current distributor unit are bonded to a laminated substrate, whereby the current distributor unit can be implemented in CMOS or bipolar technology and mounted onto an IGBT module substrate.

In accordance with an exemplary embodiment, the power semiconductor device is provided as an IGBT. In another embodiment, the current distributor unit can be arranged external to the power semiconductor module.

Exemplary embodiments of the present disclosure also provide a power semiconductor array including a plurality of modified power semiconductor modules including a plurality of power semiconductor devices, an account driver unit configured for providing reference accounts for pulling-up and/or pushing-down control contacts of the power semiconductor devices, and a modified current distributor unit configured for amplifying and/or distributing the reference currents to the power semiconductor modules. The modified power semiconductor modules each include a plurality of power semiconductor devices and a current distributor unit configured for amplifying and/or distributing the reference current to the power semiconductor devices. The current distributor unit includes a pull-up current mirror including a plurality of PMOS based transistors and a push-down current mirror including a plurality of NMOS based transistors. The first main contacts of all pull-up transistors are connected in parallel to a first voltage source, and the first main contacts of all push-down transistors are connected in parallel to a second voltage source having a lower voltage than the first voltage source. The second main contact of a respective pull-up transistor and the second main contact of a respective push-down transistor are connected together with the respective control contact of a power semiconductor device. The control contacts of the pull-up transistors are all connected in parallel to the modified current distributor unit for receiving a pull-up current, and the control contacts of the push-down transistors are all connected in parallel to the modified current distributor unit for receiving a push-down current. The modified current distributor unit includes a plurality of PMOS based transistors and a plurality of NMOS based transistors. The control contacts of the PMOS based transistors are connected together to the current driver unit for receiving the push-down current, and the control contacts of the NMOS based transistors are connected together to the current driver unit for receiving the pull-up current. The second main contact of a respective PMOS based transistor is coupled to a respective modified power semiconductor module for providing the pull-up current, and the second main contact of the respective modified power semiconductor module for providing the push-down current.

Further embodiments and advantages of the power semiconductor array are derivable by one skilled in the art from the above-described control contact driving system and/or power semiconductor module.

Exemplary embodiments of the present disclosure also provide a method for operating the aforementioned control contact driving system, the power semiconductor module and/or the power semiconductor array, whereby the current driver unit alternatively provides a positive rectangular current as pull-up reference current followed by a negative rectangular current as push-down reference current. Providing such currents allow for “switching on” respectively “switching off” the control contact of the respective power semiconductor device.

According to an exemplary embodiment, the positive rectangular current includes a rectangular current I₁ between t₁ and t₂ followed by a rectangular current I₂ between t₂ and t₃ followed by a rectangular current I₃ between t₃ and t₄, whereby I₁≧I₃≧I₂ and t₄≧t₃≧t₂≧t₁. The negative rectangular current includes a rectangular current I₅ between t₆ and t₇ followed by a rectangular current I₆ between t₇ and t₈ followed by a rectangular current I₅ between tₛ and t₉, whereby I₅≧I₆ and t₉≧t₈≧t₇≧t₆. Using such a rectangular current that succeeds behind each other improves the switching algorithm for switching on respectively off the control contacts of the power semiconductor devices.

In accordance with an exemplary embodiment, the step of detecting a malfunction comprises providing a rectangular current I₄ between t₄ and t₅, whereby I₂≧I₄ and t₅≧t₄, and/or by providing a rectangular current I₇ between t₉ and t₁₀, whereby I₇≧I₅ and t₁₀≧t₉. Thus, after before-described “transition phase” between t₁ and t₄ a “detection phase” follows between t₄ and t₅ with a lower value I₄ for power saving, whereby I₄ can flow through the reference transistor and the voltage source. The same applies for t₉ and t₁₀.

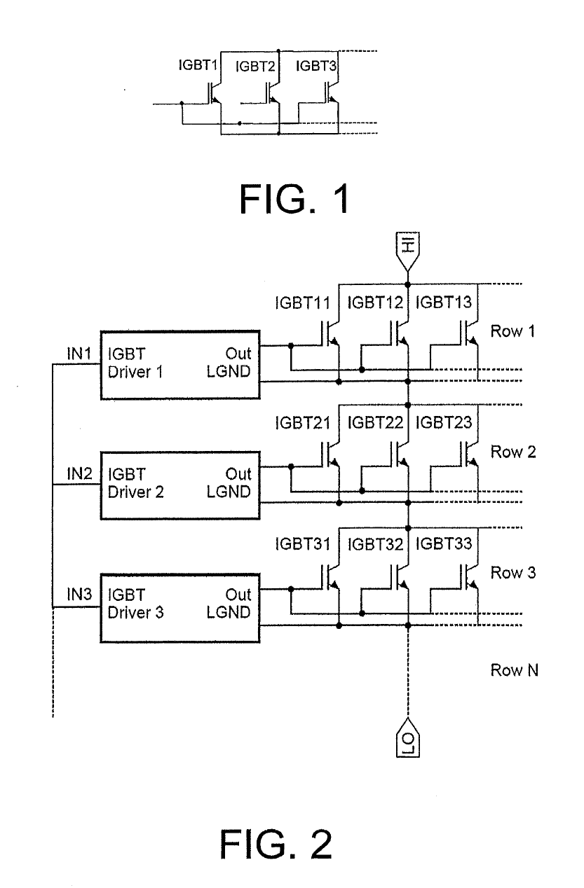

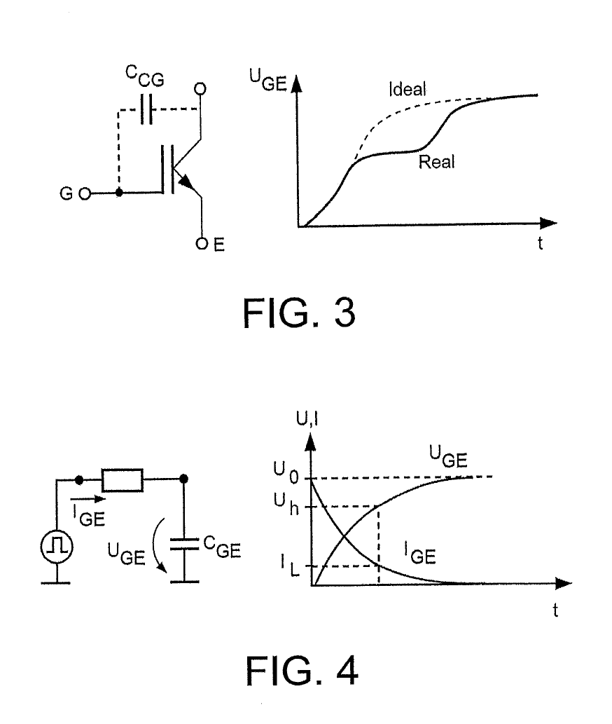

A drawback known from conventional techniques, when using parallel connections of IGBTs capsulated in a module for increasing the switching capabilities, as shown in FIG. 1, is that a gate defect and especially a short circuit connection between a gate and an emitter makes all of the IGBT devices in the module uncontrollable. For improving of a blocking voltage capability, more modules may be connected in a serial connection as shown in FIG. 2. In case of a defect in an IGBT, the overall system should continue to operate using the remaining IGBT devices with a slightly reduced current capability or to close all IGBT devices from corresponding rows and to continue to operate with respectively a slightly reduced blocking voltage capability. However, the parallel connection of the gates of the IGBTs makes such features impossible: A short circuit connection in one gate causes a voltage block for all other gates in the corresponding row. Different solutions for solving the aforementioned problem have been proposed according to known configurations.

Within a first solution, a shorted gate can be detected by the existence of gate current outside of the transition phase between switching on and off respectively off and on an IGBT device. However, the exact number of defected gates cannot be detected with such group driving. In some cases, the number of defected gates is important information that has to be known.

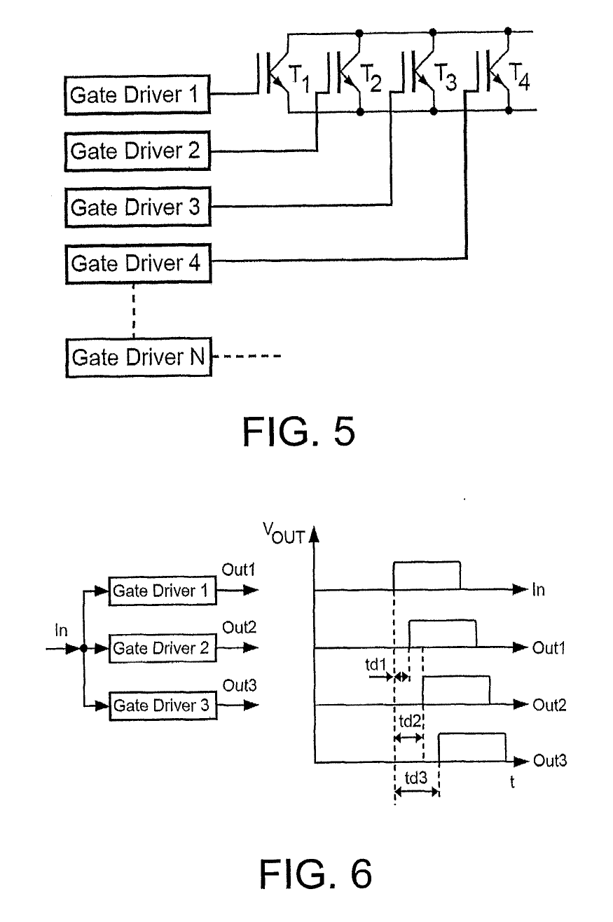

Another problem is the capacitive coupling between the collector and gate, the so-called Miller effect, as shown in FIG. 3. The capacitive coupling causes a voltage drop in the rising and falling signal edge, and delays the commutation as shown in FIG. 3.

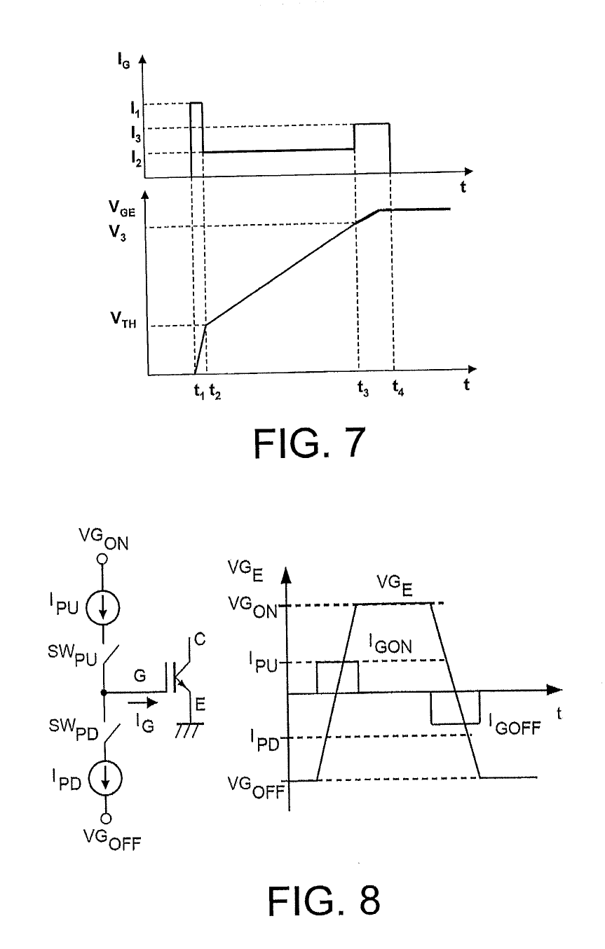

The known voltage mode control with the gate resistor limiting the switching speed has a reduced immunity against the capacitive collector gate coupling due to the exponential decreasing of the current during the transition phase. The gates of the IGBTs behave as capacitors, while two resistors may be used for charging and discharging of the gates. Eventually one resistor may be used for both processes, as shown in FIG. 4, which illustrates a simplified circuit and wave forms of the gate emitter voltage and current.

The gate voltage and current follows the equation V(t)=Vₒ*(1−e^{-(t/RC)}), I(t)=Iₒ*e^{-(t/RC)}. As can be seen from FIG. 4, and also shown by the equation, the gate voltage rises, while the gate current reduces exponentially and after a certain value the gate may become sensitive for currents pushed through the reverse collector gate coupling.

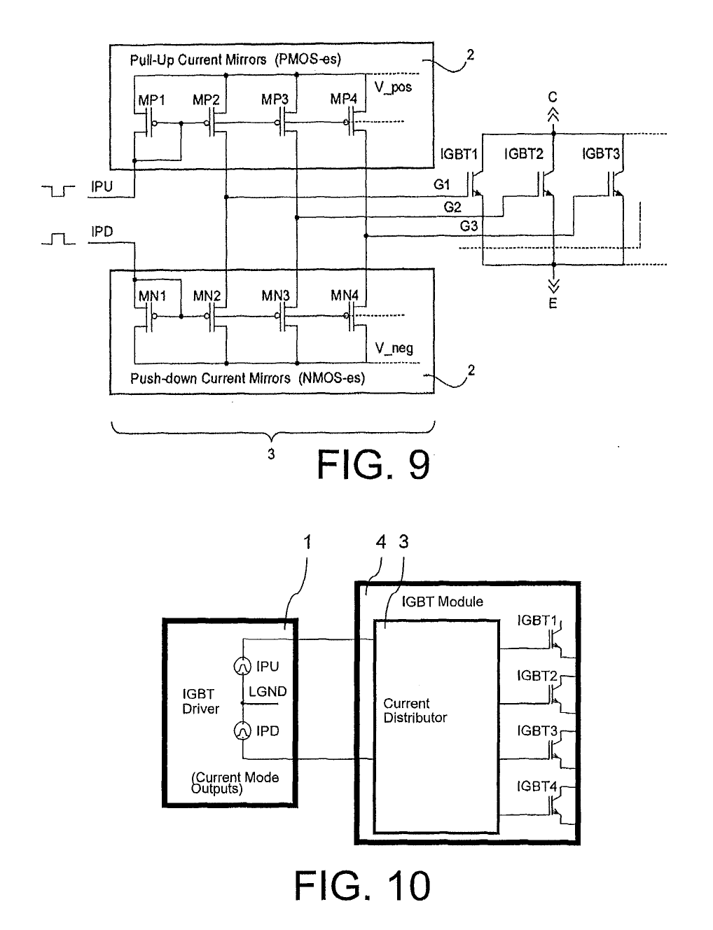

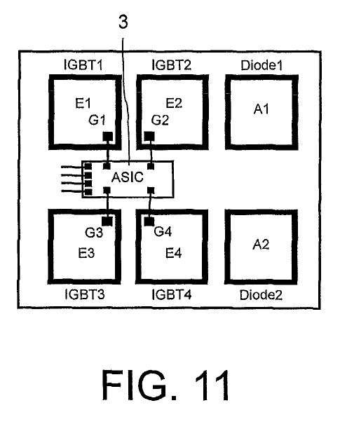

This problem has been addressed by an individual gate driving as shown in FIG. 5, whereby each gate has a dedicated gate driver. In case of failure in one gate, the remaining IGBT devices will continue to operate correctly. However, a problem in this configuration is the mismatch between the gate drivers: a gate driver usually includes a complex application specific integrated circuit (ASIC) contenting a big amount of components. Therefore, the technological tolerances often cause a big mismatch between the drivers as shown in FIG. 6.

Such mismatch causes different delays between the inputs and the outputs of the drivers, which means that some IGBTs may open earlier than others, taking the whole load for a certain moment. This weakness reduces the reliability of the overall system due to the permanent overloading of these devices. A further problem is an increased price due to the big amount of gate drivers and corresponding connections required.

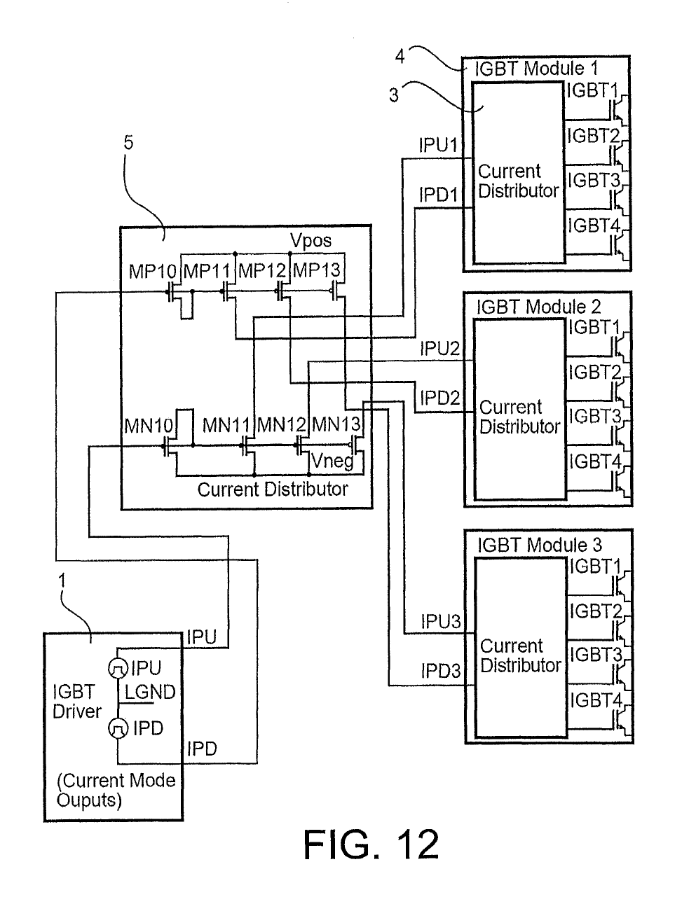

In another known solution, the applying of current mode reduces the negative influence of the aforementioned Miller effect. However, the problem with the mismatch between the drivers also remains with this solution. Another approach is the use of variable currents for realizing improved switching, for example, three current levels during the transition phase between t₁ and t₄, as shown in FIG. 7, for switching an IGBT between an off-state in t₁ to an on-state in t₄.

During an initial moment between t₁ and t₂, the gate driver pushes a higher current I₁ to the gate for faster achieving the gate threshold voltage V_{TH}. After this value, the IGBT starts to conduct and a current can be reduced to the value I₂ to limit the switching speed and respectively to protect the system from over-voltage in case of inductive load. When the gate voltage achieves a value V₃, where the reverse coupling increases its influence, for example, the capacitive sinking of current from the gate, then the gate current can be increased to the value I₃ to compensate the current lost during the final moment.

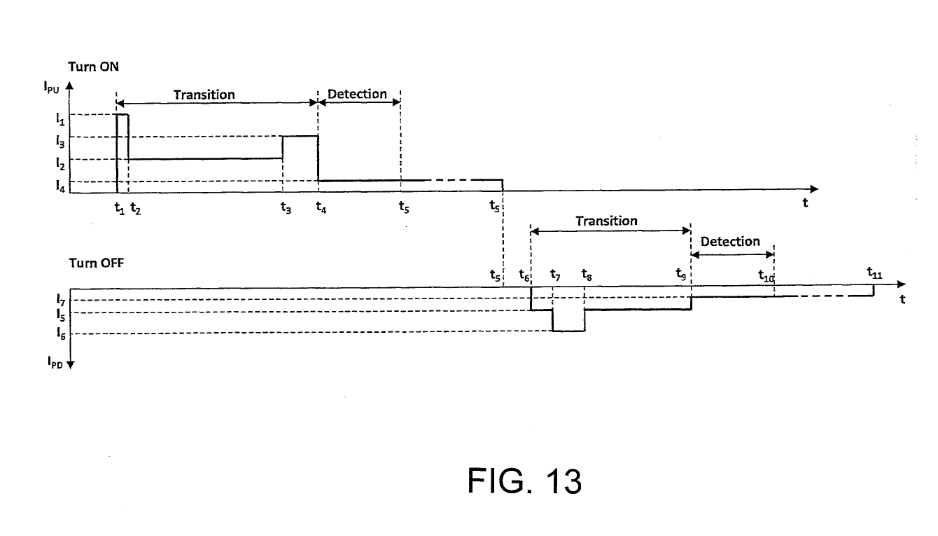

Exemplary embodiments of the present disclosure provide a current driver unit 1 that, instead of voltage, uses a constant current for controlling the gate of an IGBT, whereby the currents are applied in difference directions depending from the operation, for example, for turning on or turning off the IGBT. FIG. 8 shows an exemplary embodiment for the currents provided by the current driver unit 1.

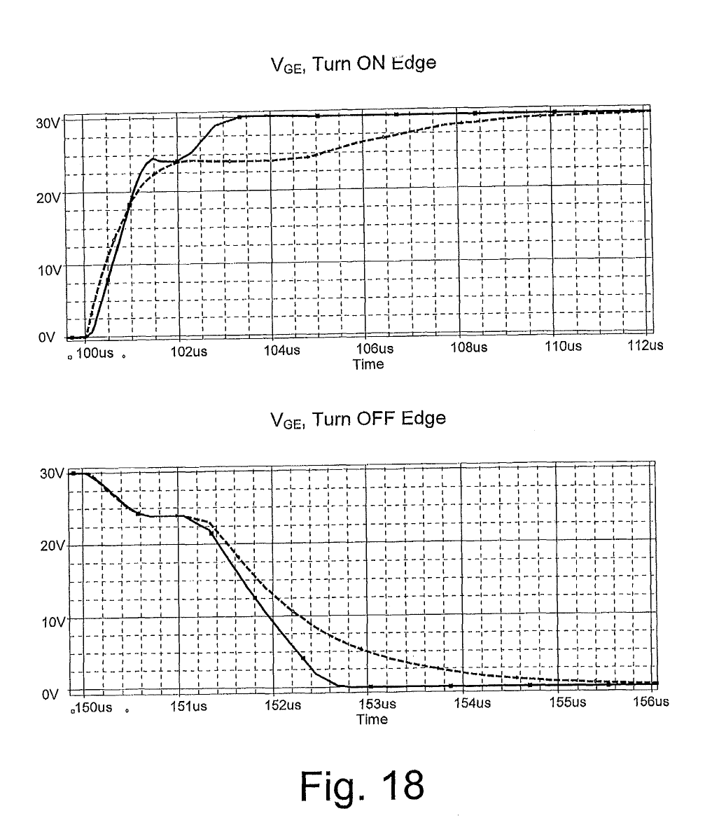

As can be seen, rectangular current pulses are used, a positive current pulse and a negative current pulse. These two current sources provide accurate currents for pulling-up and pushing-down the gate. Using such current driver unit 1, the gate voltage rises linearly with a constant speed. In other words, the currents applied to the gate causes the gate capacitance linearly raising or respectively falling voltages. The respectively rising falling voltage speed depends from the gate capacitance and the value of the pull-up and push-down currents and can be controlled by changing these currents. The charging and discharging currents have a constant value in an ideal case and exist during the transient phase only. When the gate voltage achieves the value close to the supply voltage, then the current stops the flow. The applying of constant currents thereby reduces the Miller effect, for example, the effect of coupling between the collector and the gate. Thereby, it is thoroughly possible to have more current sources and switches to provide a current shape as discussed in more detail below with reference to FIG. 13.

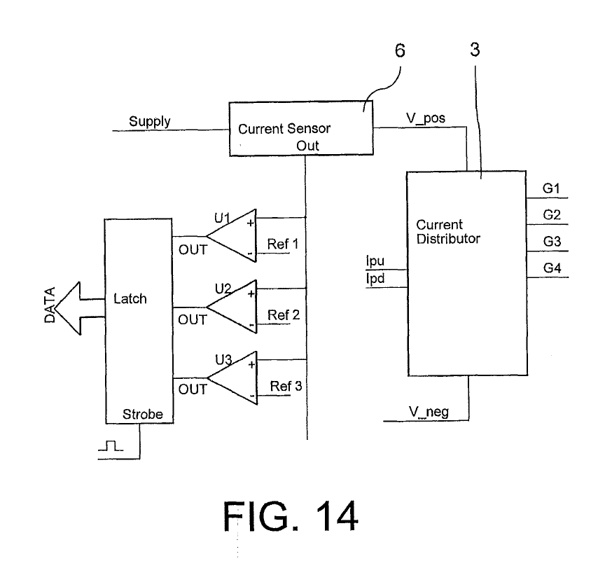

Exemplary embodiments of the present disclosure provide for the use of two current mirrors 2 making up a current distributor unit 3 to further amplify and/or distribute the current pulses of the gates of a multi-die IGBT module. In this manner, the control contact driving system can drive a plurality of gate IGBT devices, respectively. The current mirrors 2 can be implemented as a circuit, for example, as a hybrid or integrated circuit, and can be encapsulated in the IGBT module. For example, the current mirrors 2 can be provided close to the controlled IGBTs. FIG. 9 shows an exemplary embodiment of the present disclosure as described before.

The current pulses coming from the external IGBT driver, the current driver unit 1, are applied to NMOS based respectively PMOS based reference transistors MN1 and MP1. The reference transistors are in a “diode” connection, for example, and they define the bias voltage for the transistors MN2, MN3 etc. and MP2, MP3 etc.

Connecting the gate to the drain sets the operation point in the saturation area, because the drain-source voltage V_{DS} in this case is always above or equal to the saturation voltage V_{DSsat}=V_{GS}−V_{TH}. The transistors behave as current sources and their drain current can be figured out with the equation: I_{D}=(½)*μₙ*Cₒₓ*(W/L)*(V_{GS}−V_{TH})²*(1+λ*(Vos−V_{DSsat}), where μₙ is the charge-carrier effective mobility, Cₒₓ is the gate oxide capacitance per unit area, W is the gate width, L is the gate length, λ is channel-length modulation parameter and V_{DSsat}=V_{GS}−V_{TH}.

A current flowing through the drain of MN1/MP1 causes a V_{GS} satisfying the relation above. Because the same V_{GS} is applied to the other transistors, their drain currents depend from their W/L in respect to the W/L of the reference transistor, satisfying the relation below, given for the first 2 transistors MN2 and MP2:

I_{DMN2}/I_{DMN1}=(W_{MN2}/L_{MN2})/(W_{MN1}/L_{MN1})or respectively I_{DMP2}/I_{DMP1}=(W_{MP2}/L_{MP2})/(W_{MP1}/L_{MP1}).

Because of channel-length modulation, the current mirror 2 has a finite output resistance given by the rₒ of the output transistor: rₒ=1/(λ*I_{D}). The output resistance and the current accuracy can be respectively improved by utilizing cascading techniques.

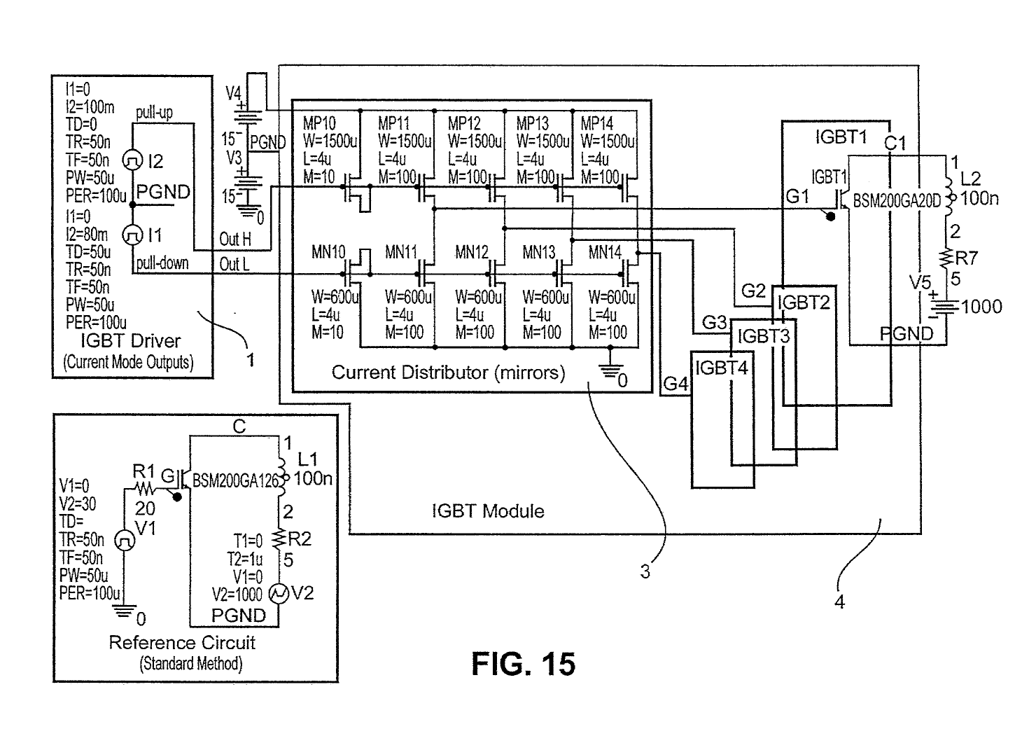

The current mirrors 2 can also amplify the input currents. As shown above, the amplification factor depends from the W/L ratio between the mirroring and the referencing transistors. In this case, the external current driver unit 1 can have a low power outputs, respectively, and the power amplification can be performed in the current distributor unit 3. In accordance with an exemplary embodiment, the current mirrors 2 can utilize a uniform structure, for example, MOS finger, repeated many times for a better matching and respective accuracy. This approach thus defines an integer amplification factor. The complete driving circuit 1, 3 will include two components, for example, the current driver unit 1 and a power semiconductor module 4 including the current distributor unit 3, as shown in FIG. 10.

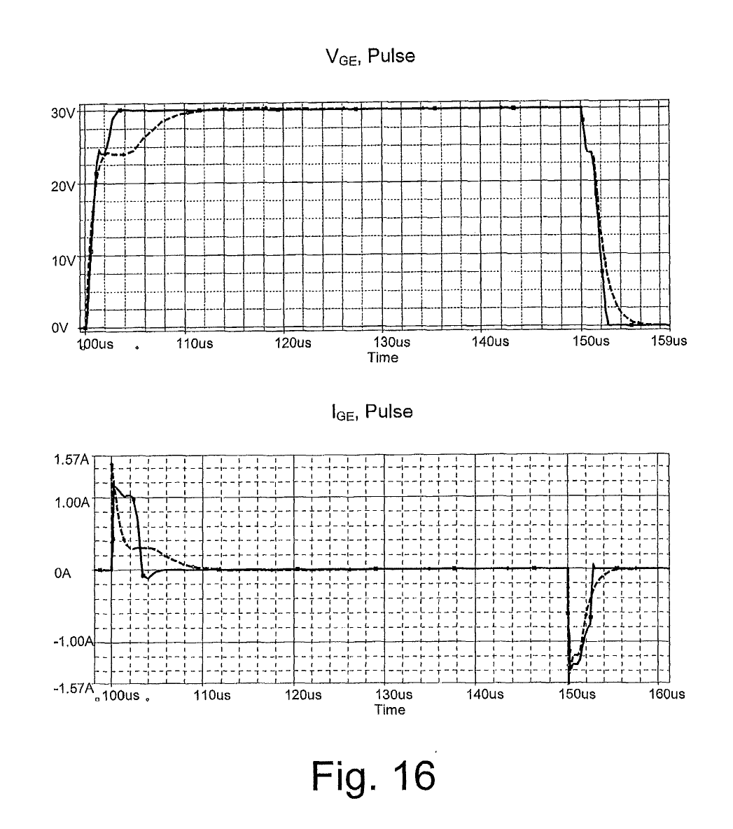

One possible placement in case of 4 IGBTs and 2 freewheeling diodes mounted on a common substrate is shown in FIG. 11.

The current driver unit 1 might be integrated in an ASIC, while in an alternative embodiment the current driver unit might also be placed externally. The current distributor unit 3 is placed between the IGBTs. The gates G1 . . . G4 are bonded to the ASIC. The ASIC is bonded to the laminated substrate and connected with metal tracks to the terminals. Four terminals are provided, for example, two inputs for pull-up and push-down currents, and two supplies. The emitters E1 . . . E4 and anodes A1, A2 may be bonded to the substrate and connected to the power terminals or alternatively contacted, pressed or soldered, and connected from the upper side.

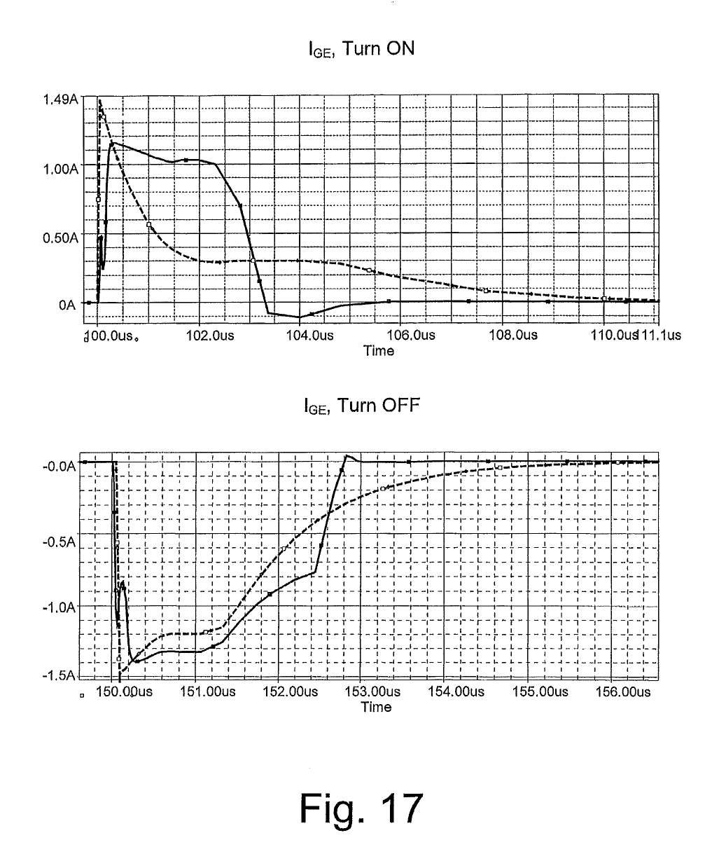

Another opportunity is the multilevel current distribution. For example, a modified current distributor unit 5 may drive other current distributors units 3, integrated in the IGBT modules. A possible configuration is presented in FIG. 12 realizing such a power semiconductor array. This hierarchical implementation allows the driving of large IGBT arrays using a single driver.

To detect shorted gates, a current sensor 6 can be introduced in the power supply of the current distributor unit 3. The current sensor 6 measures the value of the current flowing towards the current distributor unit 3 and converts it in most of the cases to a proportional voltage. One or more comparators can compare the measured value to a reference value. Outside the transition phase, only the input current flows through the supply. An exemplary waveform for the operating the control contact driving system, for example, the pull-up and push-down currents, is shown in FIG. 13.

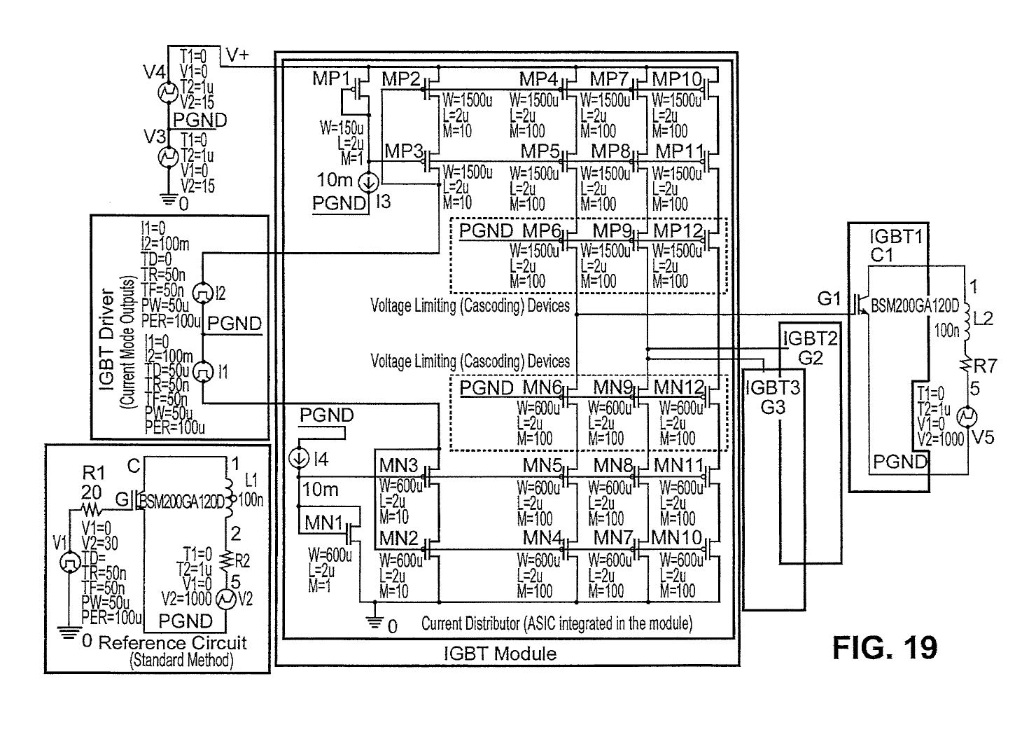

The transition phase implements the algorithm presented in FIG. 7. Alternatively, the shape of the current pulse may be different depending from the used switching algorithm. In the simplest case, the shape may be rectangular for a single current source. After the transition phase, the current applied to the current distributor unit 3 may be reduced to a lower value I₄ for power saving. The current I₄ flows through the reference transistor and the power supply. After the transition phase the gates are expected to be completely charged and they shouldn't consume current. In case of shorted gate or gates, the supply current is the sum of the current I₄ and the short circuit current or currents. The total supply current is: I_{PS}=I₄+N*(I₄*A) where N is the number of the broken gates and A is the amplification factor of the current distributor unit 3. Several comparators can compare the measured value with properly selected reference values and in such way to detect the number of the broken gates. An example is presented in FIG. 14.

The strobe pulse has to be applied within the detection phase. The data are in the so called “thermometric code”. The current sensor may have different implementations, for example: resistor with differential amplifier, current transformer, hall sensor etc.

The functionality of the current distributor was proved by simulations using 2 um CMOS technology. A small reference circuit implementing the standard method was used for a comparison.

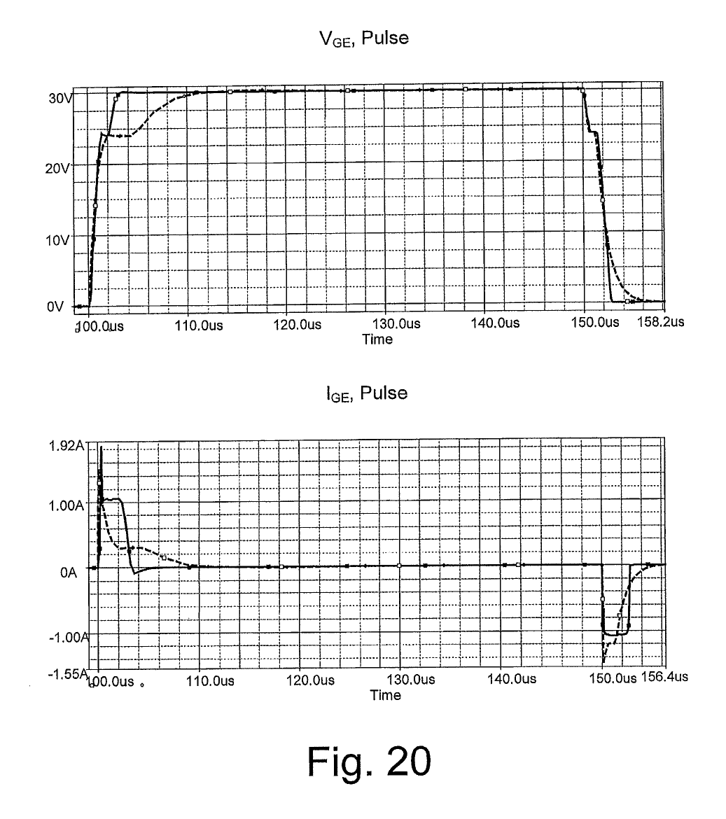

A further implementation of the current distributor is presented in FIG. 15. The schematic includes the external IGBT driver 1 presented with current pulse sources I₁ and I₂. I₂ acts as pull-up output and I₁ respectively as push-down output. The current distributor unit 3 contents the PMOS current mirrors 2 implemented with MP10 to MP14 and NMOS current mirrors 2 implemented with MN10 to MN14. The PMOS current mirrors 2 perform the pull-up operation and the NMOS current mirrors 2 the push-down operation.

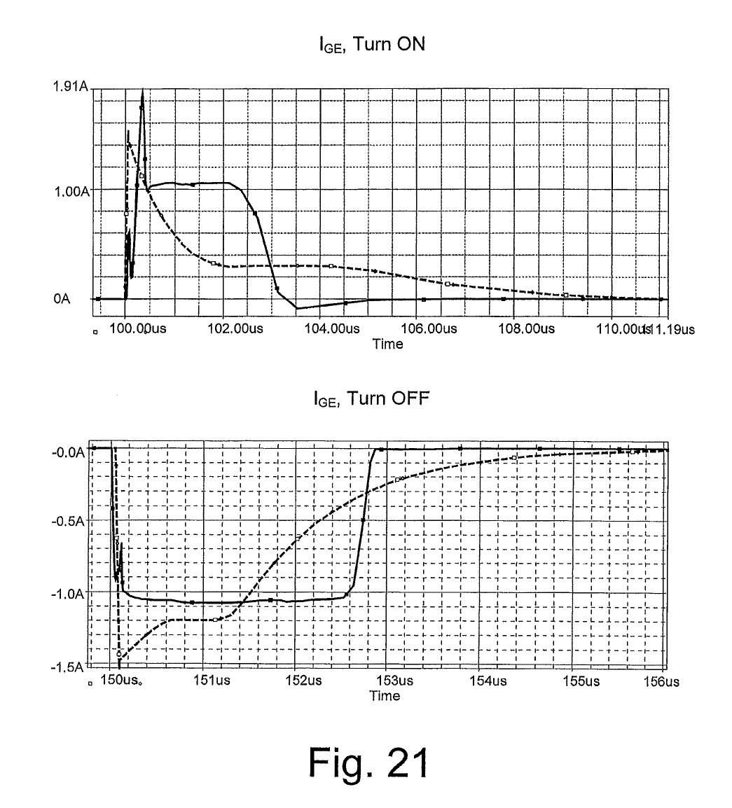

The simulation results using the control contact driving system are presented in FIGS. 16 to 18. The dotted line presents the known method. The solid line presents the method according to the present disclosure. In sum, the simulated result demonstrates an improved switching process with the method according to the present disclosure.

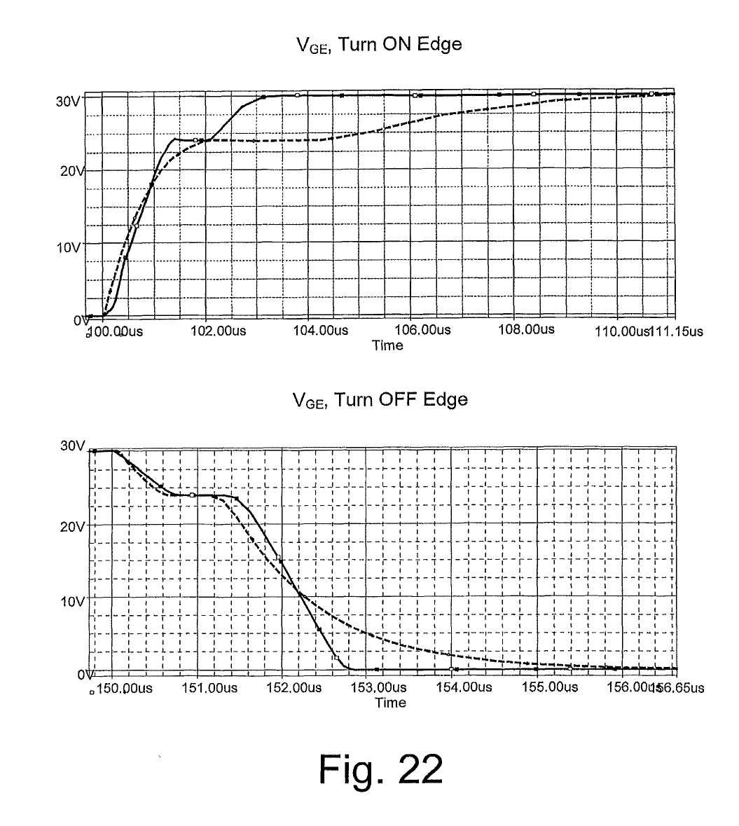

A more advanced circuit utilizing wide swing current mirrors 2 with improved characteristics and cascading transistors allowing limiting of the voltage across the output transistors and respectively using of low voltage CMOS technology for relatively high operating voltages is presented in FIG. 19. The results by using this embodiment are given in FIGS. 20 to 22 below. The waveforms of the known method are presented as dotted lines. The solid line waveforms present the method according to the present disclosure.

The embodiment from FIG. 19 demonstrates improved characteristics and especially more accurate current pulses, compared to the embodiment from FIG. 15. Another advantage is that the voltage during the OFF state is distributed over 3 MOS transistors and it allows the using of low voltage CMOS technology. The low voltage MOS transistors have better matching between the devices due to the used self-centred gate technology.

Other variations to the disclosed embodiments can be understood and effected by those skilled in the art in practicing the claimed disclosure, from a study of the drawings, the disclosure, and the appended claims. In the claims, the word “comprising” or “including” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### REFERENCE SIGNS LIST

1 Current driver unit
2 Current mirror
3 Current distributor unit
4 Power semiconductor module
5 Modified current distributor unit
6 Current sensor

What is claimed is:

1. A control contact driving system for a plurality of power semiconductor devices, comprising:
a current driver unit configured for providing reference currents for at least one of pulling-up and pushing-down control contacts of the power semiconductor devices; and
a current distributor unit configured for at least one of amplifying and distributing the reference currents to the control contacts of the power semiconductor devices, wherein:
the current distributor unit comprises a pull-up current mirror having a plurality of PMOS based transistors, and a push-down current mirror having a plurality of NMOS based transistors,
first main contacts of all pull-up transistors are connected in parallel to a first voltage source, and first main contacts of all push-down transistors are connected in parallel to a second voltage source having a lower voltage than the first voltage source;
a second main contact of a corresponding one of the pull-up transistors and a second main contact of a corresponding one of the push-down transistors are respectively connected together and configured for providing current to a respective control contact of a corresponding one of the power semiconductor devices, respectively; and
the control contacts of the pull-up transistors are all connected in parallel to the current driver unit for receiving a pull-up current, and the control contacts of the push-down transistors are all connected in parallel to the current driver unit for receiving a push-down current.

2. The control contact driving system according to claim 1, wherein:
the pull-up current mirror comprises a PMOS based pull-up reference transistor, and the push-down current mirror comprises a NMOS based push-down reference transistor;
the first main contact of the pull-up reference transistor is connected to all first main contacts of the pull-up transistors, and the first main contact of the push-down reference transistor is connected to all first main contacts of the push-down transistors;
the control contact of the pull-up reference transistor is connected to the control contacts of the pull-up transistors, and the control contact of the push-down reference transistor is connected to the control contacts of the push-down transistors; and
the second main contact of the pull-up reference transistor is connected to the current driver unit for receiving the pull-up current, and the second main contact of the push-down reference transistor is connected to the current driver unit for receiving the push-down current.

3. The control contact driving system according to claim 1, comprising:
a current sensor configured for detecting a malfunction of a control contact of a corresponding one of the power semiconductor devices,
wherein the current sensor is connected to at least one of the first main contacts of the pull-up transistors and the first main contacts of the push-down transistors.

4. The control contact driving system according to claim 1, wherein:
the pull-up current mirror comprises a plurality of PMOS based voltage limiting devices, and the push-down current mirror comprises a plurality of NMOS based voltage limiting devices; and
at least one voltage limiting device is connected in series with its main contacts between the pull-up transistor or the push-down transistor.

5. A power semiconductor module comprising:
the control contact driving system according to claim 1; and
a plurality of power semiconductor devices, wherein:
the control contact of a corresponding one of the power semiconductor devices is connected to the second main contact of a respective pull-up transistor and to the second main contact of a respective push-down transistor.

6. The power semiconductor module according to claim 5, wherein:
the power semiconductor devices are arranged in groups such that (i) the first main contacts of the power semiconductor devices of the respective group are all connected in parallel, and (ii) the second main contacts of the power semiconductor devices of the respective group are all connected in parallel.

7. The power semiconductor module according to claim 6, wherein at least the second main contacts of a first group are connected to the first main contacts of a second group.

8. The power semiconductor module according to claim 5, wherein the plurality of power semiconductor devices and the current distributor unit are bonded to a laminated substrate.

9. The power semiconductor module according to claim 5, wherein at least one of the power semiconductor device comprises an IGBT.

10. A power semiconductor array comprising a plurality of modified power semiconductor modules which include a plurality of power semiconductor devices, the array comprising:
a current driver unit configured for providing reference currents for at least one of pulling-up and pushing-down control contacts of the power semiconductor devices;
a modified current distributor unit configured for at least one of amplifying and distributing the reference currents to the power semiconductor modules, wherein:
the modified power semiconductor modules each comprise a plurality of power semiconductor devices and a current distributor unit configured for at least one of amplifying and distributing the reference currents to the power semiconductor devices;
the current distributor unit comprises a pull-up current mirror having a plurality of PMOS based transistors, and a push-down current mirror having a plurality of NMOS based transistors;
first main contacts of all pull-up transistors are connected in parallel to a first voltage source, and first main contacts of all push-down transistors are connected in parallel to a second voltage source having a lower voltage than the first voltage source;
a second main contact of a corresponding one of the pull-up transistor and a second main contact of a corresponding one of the push-down transistor are connected together with a respective control contact of a corresponding one of the power semiconductor devices, respectively;
the control contacts of the pull-up transistors are all connected in parallel to the modified current distributor unit for receiving a pull-up current, and the control contacts of the push-down transistors are all connected in parallel to the modified current distributor unit for receiving a push-down current;
the modified current distributor unit comprises a plurality of PMOS based transistors and a plurality of NMOS based transistors;
the control contacts of the PMOS based transistors are connected together to the current driver unit for receiving the push-down current, and the control contacts of the NMOS based transistors are connected together to the current driver unit for receiving the pull-up current; and
the second main contact of a corresponding one of the PMOS based transistors is coupled to a respective modified power semiconductor module for providing the pull-up current, and the second main contact of the respective modified power semiconductor module for providing the push-down current.

11. A method for operating the control contact driving system according to claim 1, the method comprising:
providing, by the current driver unit, a positive rectangular current as a pull-up reference current followed by a negative rectangular current as a push-down reference current.

12. A method according to claim 11, wherein the positive rectangular current comprises a rectangular current I₁ between t₁ and t₂ followed by a rectangular current I₂ between t₂ and t₃ followed by a rectangular current I₃ between t₃ and t₄, where I₁≧I₃≧I₂ and t₄≧t₃≧t₂≧t₁, and
wherein the negative rectangular current comprises a rectangular current I₅ between t₆ and t₇ followed by a rectangular current I₆ between t₇ and t₈ followed by a rectangular current I₅ between t₈ and t₉, where I₅≧I₆ and t₉≧t₈≧t₇≧t₆.

13. A method according to claim 13, comprising:
detecting a malfunction by at least one of (i) providing a rectangular current I₄ between t₄ and t₅, where I₂≧I₄ and t₅≧t₄, and (ii) providing a rectangular current I₇ between t₉ and t₁₀, where I₇≧₅ and t₁₀≧t₉.

14. The control contact driving system according to claim 2, comprising:
a current sensor configured for detecting a malfunction of a control contact of a corresponding one of the power semiconductor devices,
wherein the current sensor is connected to at least one of the first main contacts of the pull-up transistors and the first main contacts of the push-down transistors.

15. The control contact driving system according to claim 14, wherein:
the pull-up current mirror comprises a plurality of PMOS based voltage limiting devices, and the push-down current mirror comprises a plurality of NMOS based voltage limiting devices; and
at least one voltage limiting device is connected in series with its main contacts between the pull-up transistor or the push-down transistor.

16. The power semiconductor module according to claim 7, wherein the plurality of power semiconductor devices and the current distributor unit are bonded to a laminated substrate.

17. The power semiconductor module according to claim 7, wherein at least one of the power semiconductor devices comprises an IGBT.

18. A method for operating the control contact driving system according to claim 1, the method comprising:
providing, by the current driver unit, a positive rectangular current as a pull-up reference current followed by a negative rectangular current as a push-down reference current.

19. The method according to claim 18, wherein the positive rectangular current comprises a rectangular current I₁ between t₁ and t₂ followed by a rectangular current I₂ between t₂ and t₃ followed by a rectangular current I₃ between t₃ and t₄, where I₁≧I₃≧I₂ and t₄≧t₃≧t₂≧t₁, and
wherein the negative rectangular current comprises a rectangular current I₅ between t₆ and t₇ followed by a rectangular current I₆ between t₇ and t₈ followed by a rectangular current I₅ between t₈ and t₉, where I₅≧I₆ and t₉≧t₈≧t₇≧t₆.

20. The method according to claim 19, comprising:
detecting a malfunction by at least one of (i) providing a rectangular current I₄ between t₄ and t₅, where I₂≧I₄ and t₅≧t₄, and (ii) providing a rectangular current I₇ between t₉ and t₁₀, where I₇≧I₅ and t₁₀≧t₉.

21. A method for operating the control contact driving system according to claim 3, the method comprising:
providing, by the current driver unit, a positive rectangular current as a pull-up reference current followed by a negative rectangular current as a push-down reference current.

22. The method according to claim 21, wherein the positive rectangular current comprises a rectangular current I₁ between t₁ and t₂ followed by a rectangular current I₂ between t₂ and t₃ followed by a rectangular current I₃ between t₃ and t₄, where I₁≧I₃≧I₂ and t₄≧t₃≧t₂≧t₁, and
wherein the negative rectangular current comprises a rectangular current I₅ between t₆ and t₇ followed by a rectangular current I₆ between t₇ and t₈ followed by a rectangular current I₅ between t₈ and t₉, where I₅≧I₆ and t₉≧t₈≧t₇≧t₆.

23. A method according to claim 22, comprising:
detecting a malfunction by at least one of (i) providing a rectangular current I₄ between t₄ and t₅, where I₂≧I₄ and t₅≧t₄, and (ii) providing a rectangular current I₇ between t₉ and t₁₀, where I₇≧I₅ and t₁₀≧t₉.

24. A method for operating the power semiconductor module according to claim 5, the method comprising:
providing, by the current driver unit, a positive rectangular current as a pull-up reference current followed by a negative rectangular current as a push-down reference current.

25. The method according to claim 24, wherein the positive rectangular current comprises a rectangular current I₁ between t₁ and t₂ followed by a rectangular current I₂ between t₂ and t₃ followed by a rectangular current I₃ between t₃ and t₄, where I₁≧I₃≧I₂ and t₄≧t₃≧t₂≧t₁, and
wherein the negative rectangular current comprises a rectangular current I₅ between t₆ and t₇ followed by a rectangular current I₆ between t₇ and t₈ followed by a rectangular current I₅ between t₈ and t₉, where I₅≧I₆ and t₉≧t₈≧t₇≧t₆.

26. The method according to claim 25, comprising:
detecting a malfunction by at least one of (i) providing a rectangular current I₄ between t₄ and t₅, where I₂≧I₄ and t₅≧t₄, and (ii) providing a rectangular current I₇ between t₉ and t₁₀, where I₇≧I₅ and t₁₀≧t₉.

27. A method for operating the power semiconductor array according to claim 9, the method comprising:
providing, by the current driver unit, a positive rectangular current as a pull-up reference current followed by a negative rectangular current as a push-down reference current.

28. A method according to claim 27, wherein the positive rectangular current comprises a rectangular current I₁ between t₁ and t₂ followed by a rectangular current I₂ between t₂ and t₃ followed by a rectangular current I₃ between t₃ and t₄, where I₁≧I₃≧I₂ and t₄≧t₃≧t₂≧t₁, and
wherein the negative rectangular current comprises a rectangular current I₅ between t₆ and t₇ followed by a rectangular current I₆ between t₇ and t₈ followed by a rectangular current I₅ between t₈ and t₉, where I₅≧I₆ and t₉≧t₈≧t₇≧t₆.

29. A method according to claim 28, comprising:
detecting a malfunction by at least one of (i) providing a rectangular current I₄ between t₄ and t₅, where I₂≧I₄ and t₅≧t₄, and (ii) providing a rectangular current I₇ between t₉ and t₁₀, where I₇≧I₅ and t₁₀≧t₉.
